(19) United States
(12) Patent Application Publication
(10) Pub. No.: US 2025/0019822 A1
(43) Pub. Date: Jan. 16, 2025

(54) METAL GETTERS IN VAPORIZERS FOR IMPURITY REMOVAL

(71) Applicant: ENTEGRIS, INC., Billerica, MA (US)

(72) Inventors: Bryan C. Hendrix, Danbury, CT (US); Scott L. Battle, Cedar Park, TX (US); Dalton Vance Locklear, Cedar Park, TX (US)

(21) Appl. No.: 18/769,237

(22) Filed: Jul. 10, 2024

Related U.S. Application Data
(60) Provisional application No. 63/526,434, filed on Jul. 12, 2023.

(51) Int. Cl. C23C 16/44; C23C 16/12; C23C 16/448

(52) U.S. Cl. CPC C23C 16/4402; C23C 16/12; C23C 16/4485

(57) ABSTRACT

Metal getters in vaporizers, and related systems and methods, are provided. A vaporizer comprises a vessel having an outlet. The vessel is configured to discharge a metal halide vapor through the outlet. The vaporizer comprises a metal getter located within the vessel between the inlet and the outlet. When an oxygen-containing species is present within the vessel, an impurity content of the metal halide vapor that is discharged from the vessel is less than an impurity content of a precursor vapor that is discharged from a vessel without the metal getter.

### CROSS-REFERENCE TO RELATED APPLICATIONS

This application claims the benefit under 35 USC 119 of U.S. Provisional Patent Application No. 63/526,434, filed Jul. 12, 2023, the disclosure of which is hereby incorporated herein by reference in its entirety.

### FIELD

The present disclosure relates to the use of metal getters in vaporizers for impurity removal, and related systems and methods.

### BACKGROUND

The presence of impurities in precursors used for semiconductor fabrication results in defects and undesirable process variability. Providing precursors with sufficiently low levels of impurities remains an ongoing challenge.

### SUMMARY

Some embodiments relate to a vaporizer. In some embodiments, the vaporizer comprises a vessel having an outlet. In some embodiments, the vessel comprises a vaporizable precursor that, when vaporized, produces a metal halide vapor. In some embodiments, the vessel comprises an oxygen-containing species. In some embodiments, the vessel comprises a metal getter. In some embodiments, the metal getter is configured to reduce an impurity content of the metal halide vapor exiting through the outlet of the vessel to less than 1% by volume of an impurity based on a total volume of the metal halide vapor.

Some embodiments relate to a method for vaporizing. In some embodiments, the method comprises obtaining a vaporizer. In some embodiments, the vaporizer comprises a vessel having an inlet and an outlet. In some embodiments, the vessel comprises a vaporizable precursor. In some embodiments, the vessel comprises an oxygen-containing species. In some embodiments, the vessel comprises a metal getter. In some embodiments, the method comprises vaporizing the vaporizable precursor so as to produce a metal halide vapor. In some embodiments, the metal getter is configured to reduce an impurity content of the metal halide vapor exiting through the outlet of the vessel to less than 1% by volume of an impurity based on a total volume of the metal halide vapor.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic diagram of a cross-sectional view of a vessel, according to some embodiments.

FIG. 2 is a schematic diagram of a cross-sectional view of a vaporizer, according to some embodiments.

FIG. 3 is a flowchart of a method for vaporizing, according to some embodiments.

FIG. 4 is a schematic diagram of a cross-sectional view of a vaporizer, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

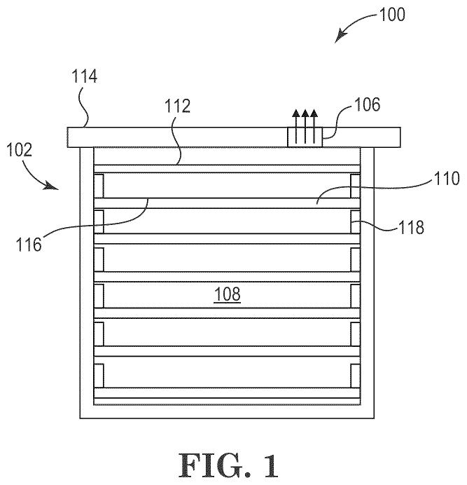

FIG. 1 is a schematic diagram of a cross-sectional view of a vaporizer 100, according to some embodiments. The vaporizer 100 may comprise a vessel 102 having an outlet 106. The vessel 102 may define an interior volume 108 of the vaporizer 100. In some embodiments, the vessel 102 is fully enclosed. In some embodiments, the vessel 102 comprises a lid 114 coupled or removably coupled to a vessel body, wherein the lid 114, when mated with the vessel body, defines the interior volume 108 of the vaporizer 100. In some embodiments, the outlet 106 is located in the lid 114. The vessel 102 may contain or may be configured to contain a vaporizable precursor, which, when vaporized, produces a precursor vapor, such as, for example and without limitation, a metal halide vapor, that is dischargeable through the outlet. In some embodiments, the vaporizer 100 comprises at least one tray 110 located within the interior volume 108 of the vessel 102. In some embodiments, the at least one tray 110 is configured to contain the vaporizable precursor. At least one of the at least one tray 110 may comprise a base 116, and a sidewall 118 extending upwards from an outer edge of the base 116. The at least one tray 110 may be configured to contact an inner surface of the vessel 102.

A metal getter 112 may be located within the vessel 102. In some embodiments, the metal getter 112 is provided in fluid communication with the precursor vapor. In some embodiments, the metal getter 112 is located within the vessel 102 such that at least a portion of the vaporizable precursor, when vaporized, contacts at least a portion of the metal getter 112. In some embodiments, the metal getter 112 is located between the vaporizable precursor and the outlet 106. In some embodiments, the metal getter 112 is located between the at least one tray 110 and the outlet 106. In some embodiments, the at least one tray 110 is one of a plurality of stacked trays located within the vessel, wherein the tray is a topmost tray of the plurality of stacked trays. In some embodiments, the at least one tray 110 may comprise a base, and a sidewall extending upwards from an outer edge of the base. In some embodiments, the metal getter 112 contacts at least a portion of a top surface of the sidewall of the at least one tray 110. In some embodiments, the metal getter 112 contacts at least a portion of a surface of the base of the at least one tray 110. In some embodiments, the metal getter 112 contacts at least a portion of a top surface of the base of the at least one tray 110. In some embodiments, the metal getter 112 is different from the at least one tray 110.

The presence of the metal getter 112 within the interior volume of the vaporizer 100 unexpectedly improves purity levels of the precursor vapor (e.g., metal halide vapor). In some embodiments, for example, when an oxygen-containing species and/or metal halide impurity is present within the vessel 102, an impurity content of the precursor vapor (e.g., metal halide vapor) that is discharged from the vessel 102 is less than (e.g., at least 5%, 10%, 15%, 20%, 25%, 30%, 35%, 40%, 45%, or 50% less than) an impurity content of a metal halide vapor that is discharged from a same or similar vessel without the metal getter. Non-limiting examples of oxygen-containing species include at least one of H₂O (v) (water vapor), O₂, or any combination thereof. Non-limiting examples of metal halide impurities include any substance containing a halide. As used herein, the impurity content may refer to a percent by volume of at least one impurity based on a total volume of the precursor vapor.

The impurity content of the precursor vapor discharged from the vessel 102 may be less than 1% (e.g., 0.000001% to 1%) by volume of at least one impurity based on a total volume of the precursor vapor. In some embodiments, the impurity content of the precursor vapor discharged from the vessel 102 may be 0.000001% to 1%, 0.000001% to 0.8%, 0.000001% to 0.6%, 0.000001% to 0.5%, 0.000001% to 0.4%, 0.000001% to 0.2%, 0.000001% to 0.1%, 0.000001% to 0.08%, 0.000001% to 0.06%, 0.000001% to 0.05%, 0.000001% to 0.04%, 0.000001% to 0.02%, 0.000001% to 0.01%, 0.000001% to 0.008%, 0.000001% to 0.006%, 0.000001% to 0.005%, 0.000001% to 0.004%, 0.000001% to 0.002%, 0.002% to 1%, 0.004% to 1%, 0.005% to 1%, 0.006% to 1%, 0.008% to 1%, 0.01% to 1%, 0.02% to 1%, 0.04% to 1%, 0.05% to 1%, 0.06% to 1%, 0.08% to 1%, 0.1% to 1%, 0.2% to 1%, 0.4% to 1%, 0.5% to 1%, 0.6% to 1%, or 0.8% to 1% by volume of the at least one impurity based on the total volume of the precursor vapor.

The metal getter may be provided in any suitable form. In some embodiments, for example, the metal getter 112 has a form of at least one of a powder, a chunk, a bead, or any combination thereof. In some embodiments, the metal getter has a form of at least one of a sheet, a foil, or any combination thereof. In some embodiments, the metal getter 112 comprises a metal plate. In some embodiments, the metal getter 112 comprises a metal sheet. In some embodiments, the metal getter 112 comprises a metal foil. In some embodiments, the metal getter 112 comprises a fibrous metal. In some embodiments, the metal getter 112 comprises a sintered metal disk. In some embodiments, the metal getter 112 is a tray 110 In some embodiments, the metal getter 112 does not comprise a sidewall. In some embodiments, a dimension (e.g., a width, a length, a diameter, a radius, etc.) the metal getter 112 is less than a dimension (e.g., a width, a length, a diameter, a radius, etc.) of the vessel 102. It will be appreciated that the metal getter 112 can have other shapes, dimensions, and forms without departing from the scope of the present disclosure.

A thickness of the metal getter 112 may be in a range of 5 microns to 1000 microns, or any range or subrange between 5 microns and 1000 microns. For example, in some embodiments, a thickness of the metal getter 112 is in a range of 5 microns to 1000 microns, 5 microns to 950 microns, 5 microns to 900 microns, 5 microns to 850 microns, 5 microns to 800 microns, 5 microns to 750 microns, 5 microns to 700 microns, 5 microns to 650 microns, 5 microns to 600 microns, 5 microns to 550 microns, 5 microns to 500 microns, 5 microns to 450 microns, 5 microns to 400 microns, 5 microns to 350 microns, 5 microns to 300 microns, 5 microns to 250 microns, 5 microns to 200 microns, 5 microns to 150 microns, 5 microns to 100 microns, 5 microns to 50 microns, 5 microns to 40 microns, 5 microns to 30 microns, 5 microns to 20 microns, 5 microns to 10 microns, 50 microns to 1000 microns, 100 microns to 1000 microns, 150 microns to 1000 microns, 200 microns to 1000 microns, 250 microns to 1000 microns, 300 microns to 1000 microns, 350 microns to 1000 microns, 400 microns to 1000 microns, 450 microns to 1000 microns, 500 microns to 1000 microns, 550 microns to 1000 microns, 600 microns to 1000 microns, 650 microns to 1000 microns, 700 microns to 1000 microns, 750 microns to 1000 microns, 800 microns to 1000 microns, 850 microns to 1000 microns, 900 microns to 1000 microns, or 950 microns to 1000 microns.

An average particle size of the metal getter 112 may be in a range of 5 microns to 500 microns, or any range or subrange between 5 microns and 500 microns. In some embodiments, an average particle size of the metal getter 112 is in a range of 5 microns to 450 microns, 5 microns to 400 microns, 5 microns to 350 microns, 5 microns to 300 microns, 5 microns to 250 microns, 5 microns to 200 microns, 5 microns to 150 microns, 5 microns to 100 microns, 5 microns to 50 microns, microns to 500 microns, 50 microns to 500 microns, 100 microns to 500 microns, microns to 500 microns, 150 microns to 500 microns, 200 microns to 500 microns, microns to 500 microns, 250 microns to 500 microns, 300 microns to 500 microns, microns to 500 microns, 350 microns to 500 microns, 400 microns to 500 microns, or 450 microns to 500 microns.

In some embodiments, the metal getter 112 has a first surface and a second surface opposite the first surface. In some embodiments, the metal getter 112 defines a plurality of holes extending from the first surface of the metal getter 112 through to the second surface of the metal getter 112. In some embodiments, the plurality of holes is arranged in a symmetric pattern. In some embodiments, the plurality of holes is arranged in an asymmetric pattern.

As used herein, the term “substantially pure” refers to a substance comprising less than 5% by volume (or weight) of at least one impurity based on a total volume (or total weight) of the substance. For example, the term “substantially pure” may refer to a substance comprising less than 5%, less than 4%, less than 3%, less than 2%, less than 1%, less than 0.1%, less than 0.01%, less than 0.001%, or less than 0.0000001% by volume (or weight) of the at least one impurity based on the total volume (or total weight) of the substance. In some embodiments, the term “substantially pure” refers to a substance in which the at least one impurity, if present, is not present at detectable levels. In some embodiments, the term “substantially pure” refers to a substance in which the at least one impurity, if present, is present at negligible levels.

As used herein, the term “substantially free” refers to a substance comprising less than 5% by volume (or weight) of at least one impurity based on a total volume (or total weight) of the substance. For example, the term “substantially pure” may refer to a substance comprising less than 5%, less than 4%, less than 3%, less than 2%, less than 1%, less than 0.1%, less than 0.01%, less than 0.001%, or less than 0.0000001% by volume (or weight) of the at least one impurity based on the total volume (or total weight) of the substance. In some embodiments, the term “substantially pure” refers to a substance in which the at least one impurity, if present, is not present at detectable levels. In some embodiments, the term “substantially pure” refers to a substance in which the at least one impurity, if present, is present at negligible levels.

The vaporizable precursor may be a solid vaporizable precursor, or the vaporizable precursor can be present in another phase, such as, for example and without limitation, at least one of a solid, a liquid, a gas, a vapor, or any combination thereof. The vaporizable precursor may comprise a metal halide. The metal halide may comprise at least one of an aluminum halide, a hafnium halide, a zirconium halide, a titanium halide, a silicone halide, a phosphorus halide, or any combination thereof. In some embodiments, the aluminum halide comprises at least one of an aluminum chloride (e.g., AlCl, AlCl₃, hydrates thereof, and the like), an aluminum bromide (e.g., AlBr, AlBr₃, Al₂Br₆, hydrates thereof, and the like), an aluminum fluoride (e.g., AlF, AlF₃, hydrates thereof, and the like), an aluminum iodide (e.g., AlI, AlI₃, hydrates thereof, and the like), or any combination thereof. In some embodiments, the hafnium halide comprises at least one of hafnium (IV) chloride (HfCl₄), hafnium (IV) bromide (HfBr₄), hafnium (IV) iodide (HfI₄), hafnium (IV) fluoride (HfF₄), hafnium (III) chloride (HfCl₃), hafnium (III) bromide (HfBr₃), hafnium (III) iodide (HfI₃), hafnium (III) fluoride (HfF₃), or any combination thereof. In some embodiments, the zirconium halide comprises at least one of ZrCl₃, ZrCl₄, hydrates thereof, or any combination thereof. In some embodiments, the titanium halide comprises at least one of TiCl₄, TiBr₄, TiF₄, TiI₄, TiCl₃, TiBr₃, TiF₃, TiCl₂, TiBr₂, TiI₂, hydrates thereof, or any combination thereof. In some embodiments, the silicone halide comprises at least one of SiCl₄, SiBr₄, SiF₄, SiI₄, hydrates thereof, or any combination thereof. In some embodiments, the phosphorus halide comprises at least one of PF₅, PCl₅, PBr₅, PBr₇, PI₅, hydrates thereof, or any combination thereof.

The precursor vapor may comprise a metal halide vapor. The metal halide vapor may comprise at least one of an aluminum halide, a hafnium halide, a zirconium halide, a titanium halide, a silicone halide, a phosphorus halide, or any combination thereof. In some embodiments, the aluminum halide comprises at least one of an aluminum chloride (e.g., AlCl, AlCl₃, hydrates thereof, and the like), an aluminum bromide (e.g., AlBr, AlBr₃, Al₂Br₆, hydrates thereof, and the like), an aluminum fluoride (e.g., AlF, AlF₃, hydrates thereof, and the like), an aluminum iodide (e.g., AlI, AlI₃, hydrates thereof, and the like), or any combination thereof. In some embodiments, the hafnium halide comprises at least one of hafnium (IV) chloride (HfCl₄), hafnium (IV) bromide (HfBr₄), hafnium (IV) iodide (HfI₄), hafnium (IV) fluoride (HfF₄), hafnium (III) chloride (HfCl₃), hafnium (III) bromide (HfBr₃), hafnium (III) iodide (HfI₃), hafnium (III) fluoride (HfF₃), or any combination thereof. In some embodiments, the zirconium halide comprises at least one of ZrCl₃, ZrCl₄, hydrates thereof, or any combination thereof. In some embodiments, the titanium halide comprises at least one of TiCl₄, TiBr₄, TiF₄, TiI₄, TiCl₃, TiBr₃, TiF₃, TiCl₂, TiBr₂, TiI₂, hydrates thereof, or any combination thereof. In some embodiments, the silicone halide comprises at least one of SiCl₄, SiBr₄, SiF₄, SiI₄, hydrates thereof, or any combination thereof. In some embodiments, the phosphorus halide comprises at least one of PF₅, PCl₅, PBr₅, PBr₇, PI₅, hydrates thereof, or any combination thereof.

The metal getter may comprise at least one of an aluminum material, an aluminum alloy material, a hafnium material, a zirconium material, a titanium material, a silicon material, a phosphorus material, or any combination thereof. In some embodiments, the metal getter may comprise at least one of a substantially pure aluminum material, an aluminum alloy material, a substantially pure hafnium material, a substantially pure zirconium material, a substantially pure titanium material, a substantially pure silicon material, a substantially pure phosphorus material, or any combination thereof. In some embodiments, the metal getter further comprises an inert material. In some embodiments, the inert material comprises carbon, silica, or a combination thereof. In some embodiments, the metal getter is substantially free of at least one of Mg, Ti, Si, Zr, Hf, Cr, Zr, V, or any combination thereof.

In some embodiments, the aluminum material comprises at least one of an aluminum powder, an aluminum chunk(s), an aluminum bead(s), an aluminum sheet, an aluminum foil, an aluminum plate, an aluminum fiber(s), a sintered aluminum disk, or any combination thereof. In some embodiments, the substantially pure aluminum material comprises at least one of a substantially pure Al powder, a substantially pure aluminum chunk(s), a substantially pure aluminum bead(s), a substantially pure aluminum sheet, a substantially pure aluminum foil, a substantially pure aluminum plate, a substantially pure aluminum fibers, a substantially pure sintered aluminum disk, or any combination thereof. In some embodiments, the aluminum alloy material comprises at least one of a 443 series aluminum alloy, a 444 series aluminum alloy, a 1050 series aluminum alloy, a 2011 series aluminum alloy, or any combination thereof. In some embodiments, the aluminum alloy material comprises at least one of Fe, Ni, Cu, or any combination thereof. In some embodiments, the aluminum alloy material is substantially free of an impurity-forming metal. In some embodiments, the impurity-forming metal comprises at least one of Mg, Ti, Si, Zr, Hf, Cr, Zr, or any combination thereof. In some embodiments, the metal getter is formed of the substantially pure aluminum material. In some embodiments, the metal getter is formed of the substantially pure aluminum alloy material.

In some embodiments, the hafnium material comprises at least one of a hafnium powder, a hafnium chunk(s), a hafnium bead(s), a hafnium sheet, a hafnium foil, a hafnium plate, a hafnium fibers, a sintered hafnium disk, or any combination thereof. In some embodiments, the substantially pure hafnium material comprises at least one of a substantially pure hafnium powder, a substantially pure hafnium chunk(s), a substantially pure hafnium bead(s), a substantially pure hafnium sheet, a substantially pure hafnium foil, a substantially pure hafnium plate, a substantially pure hafnium fibers, a substantially pure sintered hafnium disk, or any combination thereof. In some embodiments, the metal getter is formed of the substantially pure hafnium material.

In some embodiments, the zirconium material comprises at least one of a zirconium powder, a zirconium chunk(s), a zirconium bead(s), a zirconium sheet, a zirconium foil, a zirconium plate, a zirconium fibers, a sintered zirconium disk, or any combination thereof. In some embodiments, the substantially pure zirconium material comprises at least one of a substantially pure zirconium powder, a substantially pure zirconium chunk(s), a substantially pure zirconium bead(s), a substantially pure zirconium sheet, a substantially pure zirconium foil, a substantially pure zirconium plate, a substantially pure zirconium fibers, a substantially pure sintered zirconium disk, or any combination thereof. In some embodiments, the metal getter is formed of the substantially pure zirconium material.

In some embodiments, the titanium material comprises at least one of a titanium powder, a titanium chunk(s), a titanium bead(s), a titanium sheet, a titanium foil, a titanium plate, a titanium fibers, a sintered titanium disk, or any combination thereof. In some embodiments, the substantially pure titanium material comprises at least one of a substantially pure titanium powder, a substantially pure titanium chunk(s), a substantially pure titanium bead(s), a substantially pure titanium sheet, a substantially pure titanium foil, a substantially pure titanium plate, a substantially pure titanium fibers, a substantially pure sintered titanium disk, or any combination thereof. In some embodiments, the metal getter is formed of the substantially pure titanium material. In some embodiments, the metal getter does not comprise aluminum, vanadium, or aluminum and vanadium. In some embodiments, the metal getter is substantially free of aluminum. In some embodiments, the metal getter is substantially free of vanadium. In some embodiments, the metal getter is substantially free of aluminum and vanadium.

In some embodiments, the silicon material comprises at least one of a silicon powder, a silicon chunk(s), a silicon bead(s), a silicon sheet, a silicon foil, a silicon plate, a silicon fibers, a sintered silicon disk, or any combination thereof. In some embodiments, the substantially pure silicon material comprises at least one of a substantially pure silicon powder, a substantially pure silicon chunk(s), a substantially pure silicon bead(s), a substantially pure silicon sheet, a substantially pure silicon foil, a substantially pure silicon plate, a substantially pure silicon fibers, a substantially pure sintered silicon disk, or any combination thereof. In some embodiments, the metal getter is formed of the substantially pure silicon material.

In some embodiments, the phosphorus material comprises at least one of a phosphorus powder, a phosphorus chunk(s), a phosphorus bead(s), a phosphorus sheet, a phosphorus foil, a phosphorus plate, a phosphorus fibers, a sintered phosphorus disk, or any combination thereof. In some embodiments, the substantially pure phosphorus material comprises at least one of a substantially pure phosphorus powder, a substantially pure phosphorus chunk(s), a substantially pure phosphorus bead(s), a substantially pure phosphorus sheet, a substantially pure phosphorus foil, a substantially pure phosphorus plate, a substantially pure phosphorus fibers, a substantially pure sintered phosphorus disk, or any combination thereof. In some embodiments, the metal getter is formed of the substantially pure phosphorus material.

In some embodiments, the vaporizable precursor comprises an aluminum halide and the metal getter comprises a substantially pure aluminum material. In some embodiments, the vaporizable precursor comprises at least one of AlCl, AlCl₃, AlBr, AlBr₃, Al₂Br₆, AlF, AlF₃, AlI, AlI₃, or any combination thereof, and the metal getter comprises a substantially pure aluminum material. In some embodiments, the vaporizable precursor comprises an aluminum halide and the metal getter comprises an aluminum alloy material. In some embodiments, the vaporizable precursor comprises AlCl₃ and the metal getter comprises an aluminum alloy material. In some embodiments, the metal halide vapor comprises an aluminum halide and the metal getter comprises a substantially pure aluminum material. In some embodiments, the metal halide vapor comprises at least one of AlCl, AlCl₃, AlBr, AlBr₃, Al₂Br₆, AlF, AlF₃, AlI, AlI₃, or any combination thereof, and the metal getter comprises a substantially pure aluminum material. In some embodiments, the metal halide vapor comprises an aluminum halide and the metal getter comprises an aluminum alloy material. In some embodiments, the metal halide vapor comprises AlCl₃ and the metal getter comprises an aluminum alloy material.

In some embodiments, the vaporizable precursor comprises a hafnium halide and the metal getter comprises a substantially pure hafnium material. In some embodiments, the vaporizable precursor comprises at least one of HfCl₄, HfBr₄, HfI₄, HfF₄, HfCl₃, HfBr₃, HfI₃, HfF₃, or any combination thereof, and the metal getter comprises a substantially pure hafnium material. In some embodiments, the metal halide vapor comprises a hafnium halide and the metal getter comprises a substantially pure hafnium material. In some embodiments, the metal halide vapor comprises at least one of HfCl₄, HfBr₄, HfI₄, HfF₄, HfCl₃, HfBr₃, HfI₃, HfF₃, or any combination thereof, and the metal getter comprises a substantially pure hafnium material.

In some embodiments, the vaporizable precursor comprises a zirconium halide and the metal getter comprises a substantially pure zirconium material. In some embodiments, the vaporizable precursor comprises ZrCl₃, ZrCl₄, or any combination thereof, and the metal getter comprises a substantially pure zirconium material. In some embodiments, the metal halide vapor comprises a zirconium halide and the metal getter comprises a substantially pure zirconium material. In some embodiments, the metal halide vapor comprises ZrCl₃, ZrCl₄, or any combination thereof, and the metal getter comprises a substantially pure zirconium material.

In some embodiments, the vaporizable precursor comprises a titanium halide and the metal getter comprises a substantially pure titanium material. In some embodiments, the vaporizable precursor comprises at least one of TiCl₄, TiBr₄, TiF₄, TiI₄, TiCl₃, TiBr₃, TiF₃, TiCl₂, TiBr₂, TiI₂, or any combination thereof, and the metal getter comprises a substantially pure titanium material. In some embodiments, the metal halide vapor comprises a titanium halide and the metal getter comprises a substantially pure titanium material. In some embodiments, the metal halide vapor comprises at least one of TiCl₄, TiBr₄, TiF₄, TiI₄, TiCl₃, TiBr₃, TiF₃, TiCl₂, TiBr₂, TiI₂, or any combination thereof, and the metal getter comprises a substantially pure titanium material.

In some embodiments, the vaporizable precursor comprises a silicon halide and the metal getter comprises a substantially pure silicon material. In some embodiments, the vaporizable precursor comprises at least one of SiCl₄, SiBr₄, SiF₄, SiI₄, or any combination thereof, and the metal getter comprises a substantially pure silicon material. In some embodiments, the metal halide vapor comprises a silicon halide and the metal getter comprises a substantially pure silicon material. In some embodiments, the metal halide vapor comprises at least one of SiCl₄, SiBr₄, SiF₄, SiI₄, or any combination thereof, and the metal getter comprises a substantially pure silicon material.

In some embodiments, the vaporizable precursor comprises a phosphorus halide and the metal getter comprises a substantially pure phosphorus material. In some embodiments, the vaporizable precursor comprises at least one of PF₅, PCl₅, PBr₅, PBr₇, PI₅, or any combination thereof, and the metal getter comprises a substantially pure phosphorus material. In some embodiments, the metal halide vapor comprises a phosphorus halide and the metal getter comprises a substantially pure phosphorus material. In some embodiments, the metal halide vapor comprises at least one of PF₅, PCl₅, PBr₅, PBr₇, PI₅, or any combination thereof, and the metal getter comprises a substantially pure phosphorus material.

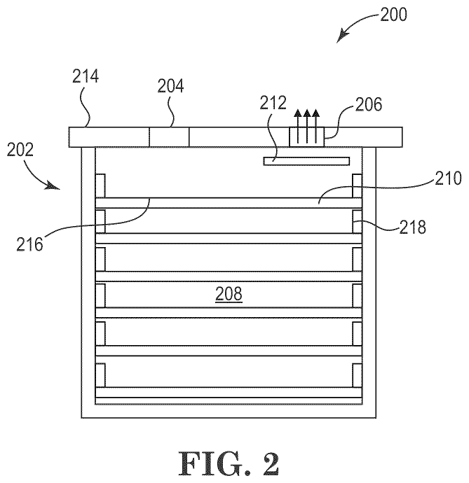

FIG. 2 is a schematic diagram of a cross-sectional view of a vaporizer 200, according to some embodiments. The vaporizer 200 may comprise a vessel 202 having an inlet 204 and an outlet 206. The vessel 202 may define an interior volume 208 of the vaporizer 200. In some embodiments, the vessel 202 is fully enclosed. In some embodiments, the vessel 202 comprises a lid 214 coupled or removably coupled to a vessel body, wherein the lid 214, when mated with the vessel body, defines the interior volume 208 of the vaporizer 200. In some embodiments, at least one of the inlet 204, the outlet 206, or any combination thereof, is located in the lid 214. The vessel 202 may contain or may be configured to contain a vaporizable precursor, which, when vaporized, produces a precursor vapor, such as, for example and without limitation, a metal halide vapor, that is dischargeable through the outlet. In some embodiments, the vaporizer 200 comprises at least one tray 210 located within the interior volume 208 of the vessel 202. In some embodiments, the at least one tray 210 is configured to contain the vaporizable precursor. At least one of the at least one tray 210 may comprise a base 216, and a sidewall 218 extending upwards from an outer edge of the base 216. The at least one tray 210 may be configured to contact an inner surface of the vessel 202. In some embodiments, the metal getter 212 is located between a topmost tray of the at least one tray 210 and the outlet 206.

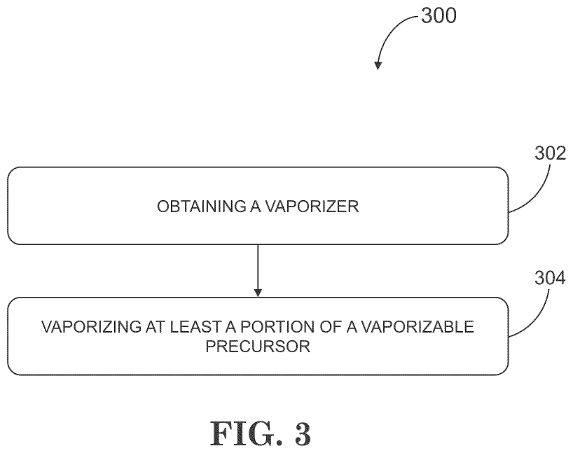

FIG. 3 is a flowchart of a method for vaporizing, according to some embodiments. As shown in FIG. 3, in some embodiments, the method comprises obtaining 302 a vaporizer. In some embodiments, the vaporizer comprises a vessel having an inlet and an outlet. In some embodiments, the vaporizer comprises a metal getter located within the vessel. In some embodiments, the vessel contains a vaporizable precursor that, when vaporized, produces a metal halide vapor. In some embodiments, the vessel is configured to discharge the metal halide vapor through the outlet. In some embodiments, the method comprises vaporizing 304 at least a portion of the vaporizable precursor so as to produce a precursor vapor. In some embodiments, when an oxygen species or a metal halide impurity is present within the vessel, an impurity content of the precursor vapor that is discharged from the vessel is less than an impurity content of a precursor vapor that is discharged from a vessel without the metal getter.

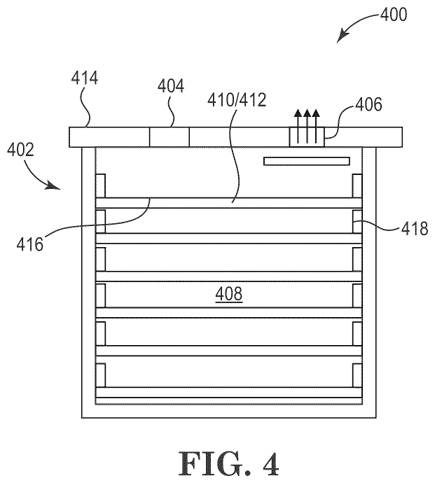

FIG. 4 is a schematic diagram of a cross-sectional view of a vaporizer 400, according to some embodiments. In FIG. 4, the getter 412 also functions as the tray. The vaporizer 400 may comprise a vessel 402 having an inlet 404 and an outlet 406. The vessel 402 may define an interior volume 408 of the vaporizer 400. In some embodiments, the vessel 402 is fully enclosed. In some embodiments, the vessel 402 comprises a lid 414 coupled or removably coupled to a vessel body, wherein the lid 414, when mated with the vessel body, defines the interior volume 408 of the vaporizer 400. In some embodiments, at least one of the inlet 404, the outlet 406, or any combination thereof, is located in the lid 414. The vessel 402 may contain or may be configured to contain a vaporizable precursor, which, when vaporized, produces a precursor vapor, such as, for example and without limitation, a metal halide vapor, that is dischargeable through the outlet. In this embodiment, the vaporizer 400 includes at least one tray 410 located within the interior volume 408 of the vessel 402. The at least one tray 410 is configured to contain the vaporizable precursor. The at least one tray 410 also serves as the getter. At least one of the at least one tray 410 may comprise a base 416, and a sidewall 418 extending upwards from an outer edge of the base 416. The at least one tray 410 may be configured to contact an inner surface of the vessel 402. In an embodiment, the tray 410 is formed of a 443 series aluminum alloy, a 444 series aluminum alloy, a 1050 series aluminum alloy, or a 2011 series aluminum alloy such that it can function as a getter 412.

### Aspects

Various Aspects are described below. It is to be understood that any one or more of the features recited in the following Aspect(s) can be combined with any one or more other Aspect(s).

Aspect 1. A vaporizer comprising:
a vessel having an outlet, the vessel containing:
   a vaporizable precursor that, when vaporized, produces a metal halide vapor;
   an oxygen-containing species; and
   a metal getter;
      wherein the metal getter is configured to reduce an impurity content of the metal halide vapor exiting through the outlet of the vessel to less than 1% by volume of an impurity based on a total volume of the metal halide vapor.

Aspect 2. The vaporizer according to Aspect 1, wherein the vessel comprises:
a vessel body; and
a lid removably coupled to the vessel body,
   wherein the lid, when mated with the vessel body, defines an interior volume of the vessel body;
   wherein the outlet of the vessel is located in the lid.

Aspect 3. The vaporizer according to any one of Aspects 1-2, further comprising:
a tray located within the vessel,
   wherein the tray is configured to support the vaporizable precursor;
   wherein the metal getter is located within the vessel between the tray and the outlet;
   wherein the tray is different from the metal getter.

Aspect 4. The vaporizer according to Aspect 3, wherein the tray is one of a plurality of stacked trays located within the vessel, wherein the tray is a topmost tray of the plurality of stacked trays.

Aspect 5. The vaporizer according to Aspect 3, wherein:
the tray comprises:
   a base; and
   a sidewall extending upwards from an outer edge of the base; and
the metal getter is located on at least a portion of the tray.

Aspect 6. The vaporizer according to Aspect 5, wherein the metal getter contacts at least a portion of a top surface of the sidewall of the tray.

Aspect 7. The vaporizer according to Aspect 6, wherein the metal getter contacts at least a portion of a top surface of the base of the tray.

Aspect 8. The vaporizer according to any one of Aspects 1-7, wherein a width of the metal getter is less than a width of the vessel.

Aspect 9. The vaporizer according to any one of Aspects 1-8, wherein the metal getter has a form of at least one of a powder, a chunk, a bead, or any combination thereof.

Aspect 10. The vaporizer according to any one of Aspects 1-9, wherein the metal getter does not comprise a sidewall.

Aspect 11. The vaporizer according to any one of Aspects 1-10, wherein the metal getter comprises a metal plate.

Aspect 12. The vaporizer according to any one of Aspects 1-11, wherein the metal getter comprises a metal sheet.

Aspect 13. The vaporizer according to any one of Aspects 1-12, wherein the metal getter comprises a metal foil.

Aspect 14. The vaporizer according to any one of Aspects 1-13, wherein the metal getter comprises a fibrous metal.

Aspect 15. The vaporizer according to any one of Aspects 1-14, wherein the metal getter comprises a sintered metal disk.

Aspect 16. The vaporizer according to any one of Aspects 1-15, wherein the metal getter has a first surface and a second surface opposite the first surface, wherein the metal getter defines a plurality of holes extending from the first surface of the metal getter through to the second surface of the metal getter.

Aspect 17. The vaporizer according to Aspect 1, further comprising an inlet.

Aspect 18. The vaporizer according to Aspect 1, wherein the getter is a tray.

Aspect 19. The vaporizer according to any one of Aspects 1-18, wherein the metal getter is formed of a substantially pure Al material, an aluminum alloy material, a substantially pure hafnium material, a substantially pure zirconium material, a substantially pure titanium material, a substantially pure silicon material, or a substantially pure phosphorus material.

Aspect 20. The vaporizer according to any one of Aspects 1-19, wherein the metal getter is formed of a 443 series aluminum alloy, a 444 series aluminum alloy, a 1050 series aluminum alloy, or a 2011 series aluminum alloy.

Aspect 21. The vaporizer according to any one of Aspects 1-20, wherein the metal getter is substantially free of at least one of Mg, Ti, Si, Zr, Hf, Cr, Zr, V, or any combination thereof.

Aspect 22. The vaporizer according to any one of Aspects 1-21, wherein the oxygen-containing species comprises at least one of H₂O, O₂, or any combination thereof.

Aspect 23. The vaporizer according to any one of Aspects 1-22, wherein the impurity content of the metal halide vapor is 0.000001% to 1% by volume of the impurity based on the total volume of the metal halide vapor.

Aspect 24. The vaporizer according to any one of Aspects 1-23, wherein the metal halide vapor comprises AlCl₃ and wherein the metal getter comprises a substantially pure Al material.

Aspect 25. The vaporizer according to any one of Aspects 1-24, wherein the metal halide vapor comprises AlCl₃ and wherein the metal getter comprises an Al alloy material.

Aspect 26. The vaporizer according to Aspect 25, wherein the Al alloy material comprises a 443 series aluminum alloy, a 444 series aluminum alloy, a 1050 series aluminum alloy, or a 2011 series aluminum alloy.

Aspect 27. The vaporizer according to Aspect 25, wherein the Al alloy material is substantially free of an impurity-forming metal.

Aspect 28. The vaporizer according to Aspect 27, wherein the impurity-forming metal comprises at least one of Mg, Ti, Si, Zr, Hf, Cr, Zr, or any combination thereof.

Aspect 29. The vaporizer according to Aspect 25, wherein the Al alloy material comprises at least one of Fe, Ni, Cu, or any combination thereof.

Aspect 30. The vaporizer according to any one of Aspects 1-29, wherein the metal halide vapor comprises HfCl₄ and wherein the metal getter comprises a substantially pure Hf material.

Aspect 31. The vaporizer according to any one of Aspects 1-30, wherein the metal halide vapor comprises ZrCl₄ and wherein the metal getter comprises a substantially pure Zr material.

Aspect 32. The vaporizer according to any one of Aspects 1-31, wherein the metal halide vapor comprises TiCl₄ and wherein the metal getter comprises a substantially pure Ti material.

Aspect 33. The vaporizer according to any one of Aspects 1-32, wherein the metal getter does not comprise Al, V, or Al and V.

Aspect 34. The vaporizer according to any one of Aspects 1-33, wherein the metal halide vapor comprises SiCl₄ and wherein the metal getter comprises a substantially pure Si material.

Aspect 35. The vaporizer according to any one of Aspects 1-34, wherein the metal getter further comprises an inert material.

Aspect 36. The vaporizer according to Aspect 35, wherein the inert material comprises carbon, silica, or a combination thereof.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A vaporizer comprising:
a vessel having an outlet, the vessel containing:
a vaporizable precursor that, when vaporized, produces a metal halide vapor;
an oxygen-containing species; and
a metal getter;
wherein the metal getter is configured to reduce an impurity content of the metal halide vapor exiting through the outlet of the vessel to less than 1% by volume of an impurity based on a total volume of the metal halide vapor.

2. The vaporizer of claim 1, wherein the vessel comprises:
a vessel body; and
a lid removably coupled to the vessel body,
wherein the lid, when mated with the vessel body, defines an interior volume of the vessel body;
wherein the outlet of the vessel is located in the lid.

3. The vaporizer of claim 1, further comprising:
a tray located within the vessel,
wherein the tray is configured to support the vaporizable precursor;
wherein the metal getter is located within the vessel between the tray and the outlet;
wherein the tray is different from the metal getter.

4. The vaporizer of claim 3, wherein the tray is one of a plurality of stacked trays located within the vessel, wherein the tray is a topmost tray of the plurality of stacked trays.

5. The vaporizer of claim 3, wherein:
the tray comprises:
a base; and
a sidewall extending upwards from an outer edge of the base; and
the metal getter is located on at least a portion of the tray.

6. The vaporizer of claim 5, wherein the metal getter contacts at least a portion of a top surface of the sidewall of the tray.

7. The vaporizer of claim 6, wherein the metal getter contacts at least a portion of a top surface of the base of the tray.

8. The vaporizer of claim 1, wherein a width of the metal getter is less than a width of the vessel.

9. The vaporizer of claim 1, wherein the metal getter has a form of at least one of a powder, a chunk, a bead, or any combination thereof.

10. The vaporizer of claim 1, wherein the metal getter does not comprise a sidewall.

11. The vaporizer of claim 1, wherein the metal getter comprises a metal plate.

12. The vaporizer of claim 1, wherein the metal getter comprises a metal sheet.

13. The vaporizer of claim 1, wherein the metal getter comprises a metal foil.

14. The vaporizer of claim 1, wherein the metal getter comprises a fibrous metal.

15. The vaporizer of claim 1, wherein the metal getter comprises a sintered metal disk.

16. The vaporizer of claim 1, wherein the metal getter has a first surface and a second surface opposite the first surface, wherein the metal getter defines a plurality of holes extending from the first surface of the metal getter through to the second surface of the metal getter.

17. The vaporizer of claim 1, further comprising an inlet.

18. The vaporizer of claim 1, wherein the getter is a tray.

19. The vaporizer of claim 1, wherein the metal getter is formed of a substantially pure Al material, an aluminum alloy material, a substantially pure hafnium material, a substantially pure zirconium material, a substantially pure titanium material, a substantially pure silicon material, or a substantially pure phosphorus material.

20. The vaporizer of claim 1, wherein the metal getter is formed of a 443 series aluminum alloy, a 444 series aluminum alloy, a 1050 series aluminum alloy, or a 2011 series aluminum alloy.

21. The vaporizer of claim 1, wherein the metal getter is substantially free of at least one of Mg, Ti, Si, Zr, Hf, Cr, Zr, V, or any combination thereof.

22. The vaporizer of claim 1, wherein the oxygen-containing species comprises at least one of H₂O, O₂, or any combination thereof.

23. The vaporizer of claim 1, wherein the impurity content of the metal halide vapor is 0.000001% to 1% by volume of the impurity based on the total volume of the metal halide vapor.

24. The vaporizer of claim 1, wherein the metal halide vapor comprises AlCl₃ and wherein the metal getter comprises a substantially pure Al material.

25. The vaporizer of claim 1, wherein the metal halide vapor comprises AlCl₃ and wherein the metal getter comprises an Al alloy material.

26. The vaporizer of claim 25, wherein the Al alloy material comprises a 443 series aluminum alloy, a 444 series aluminum alloy, a 1050 series aluminum alloy, or a 2011 series aluminum alloy.

27. The vaporizer of claim 25, wherein the Al alloy material is substantially free of an impurity-forming metal.

28. The vaporizer of claim 27, wherein the impurity-forming metal comprises at least one of Mg, Ti, Si, Zr, Hf, Cr, Zr, or any combination thereof.

29. The vaporizer of claim 25, wherein the Al alloy material comprises at least one of Fe, Ni, Cu, or any combination thereof.

30. The vaporizer of claim 1, wherein the metal halide vapor comprises HfCl₄ and wherein the metal getter comprises a substantially pure Hf material.

31. The vaporizer of claim 1, wherein the metal halide vapor comprises ZrCl₄ and wherein the metal getter comprises a substantially pure Zr material.

32. The vaporizer of claim 1, wherein the metal halide vapor comprises TiCl₄ and wherein the metal getter comprises a substantially pure Ti material.

33. The vaporizer of claim 1, wherein the metal getter does not comprise Al, V, or Al and V.

34. The vaporizer of claim 1, wherein the metal halide vapor comprises SiCl₄ and wherein the metal getter comprises a substantially pure Si material.

35. The vaporizer of claim 1, wherein the metal getter further comprises an inert material.

36. The vaporizer of claim 35, wherein the inert material comprises carbon, silica, or a combination thereof.
